(19) United States
(12) Patent Application Publication
(10) Pub. No.: US 2006/0150896 A1
(43) Pub. Date: Jul. 13, 2006

(54) Labware for high-throughput free-interface diffusion crystallization

(75) Inventors: Brent W. Segelke, San Ramon, CA (US); Timothy P. Lekin, Livermore, CA (US); Dominique Toppani, Livermore, CA (US)

Correspondence Address: Eddie E. Scott;Assistant Laboratory Counsel, Lawrence Livermore National Laboratory, L-703, P.O. Box 808, Livermore, CA, 94551, US

(73) Assignee: The Regents of the University of California

(21) Appl. No.: 11/172,685

(22) Filed: Jun. 30, 2005

Related U.S. Application Data
(60) Provisional application No. 60/642,858, filed on Jan. 10, 2005.

(51) Int. Cl. C30B 11/00

(52) U.S. Cl. 117/206

(57) ABSTRACT

A system for crystallization of a protein sample comprising a first mixing cell, a reagent cocktail that is adapted to be added to the first mixing cell, a second mixing cell with the protein sample adapted to be added to the second mixing cell, and a transfer device between the first mixing cell and the second mixing cell. The transfer device comprises structure that allows the reagent cocktail in the first mixing cell to flow into the second mixing cell and mix with the protein sample and allows the protein sample in the second mixing cell to flow into the first mixing cell and mix with the reagent cocktail. The mixture of the reagent cocktail and the protein sample are allowed to incubate to produce protein crystals.

### CROSS-REFERENCE TO RELATED APPLICATIONS

This application claims the benefit of U.S. Provisional Patent Application No. 60/642,858 by Brent W. Segelke, Timothy P. Lekin, and Dominique Toppani filed Jan. 10, 2005 and titled “Labware for High-Throughput Free-Interface Diffusion Crystallization.” U.S. Provisional Patent Application No. 60/642,858 filed Jan. 10, 2005 is incorporated herein by this reference.

The United States Government has rights in this invention pursuant to Contract No. W-7405-ENG-48 between the United States Department of Energy and the University of California for the operation of Lawrence Livermore National Laboratory.

### BACKGROUND

1. Field of Endeavor

The present invention relates to X-ray crystallography and more particularly to Labware for high-throughput free-interface diffusion crystallization.

2. State of Technology

U.S. Pat. No. 5,597,457 for a system and method for forming synthetic protein crystals to determine the conformational structure by crystallography to George D. Craig, issued Jan. 28, 1997 provides the following background information, “The conformational structure of proteins is a key to understanding their biological functions and to ultimately designing new drug therapies. The conformational structures of proteins are conventionally determined by x-ray diffraction from their crystals. Unfortunately, growing protein crystals of sufficient high quality is very difficult in most cases, and such difficulty is the main limiting factor in the scientific determination and identification of the structures of protein samples. Prior art methods for growing protein crystals from super-saturated solutions are tedious and time-consuming, and less than two percent of the over 100,000 different proteins have been grown as crystals suitable for x-ray diffraction studies.”

International Patent No. WO0109595 A2 for a method and system for creating a crystallization results database to Lansing Stewart et al., published Feb. 8, 2001, provides the following background information, “Macromolecular x-ray crystallography is an essential aspect of modern drug discovery and molecular biology. Using x-ray crystallographic techniques, the three-dimensional structures of biological macromolecules, such as proteins, nucleic acids, and their various complexes, can be determined at practically atomic level resolution. The enormous value of three-dimensional information has led to a growing demand for innovative products in the area of protein crystallization, which is currently the major rate limiting step in x-ray structure determination. One of the first and most important steps of the x-ray crystal structure determination of a target macromolecule is to grow large, well diffracting crystals with the macromolecule. As techniques for collecting and analyzing x-ray diffraction data have become more rapid and automated, crystal growth has become a rate limiting step in the structure determination process.”

U.S. Pat. No. 6,368,402 for a method for growing crystals to George T. DeTitta et al, issued Apr. 9, 2002, provides the following background information, “A number of investigators have attempted to condense their experiences in the crystal growth laboratory into a list of recipes of reagents that have found success as crystallizing agents.” The most used of these is the list compiled by Jancarik, J. and Kim, S.-H. (1991), J. Appl. Cryst. 24, 409-411 which is often referred to as the “sparse matrix sampling” screen. The list is a “heavily biased” selection of conditions out of many variables including sampling pH, additives and precipitating agents. The bias is a reflection of personal experience and literature reference towards pH values, additives and agents that have successfully produced crystals in the past. Commercialization of the sparse matrix screen has led to its popularity; easy and simple to use, it is often the first strategy in the crystal growth lab. The agents chosen by Jancarik and Kim are designed to maximize the frequency of precipitation outcomes for a broad variety of proteins. They were chosen because in a large percentage of experiments employing them “something happened.”

U.S. Pat. No. 5,961,934 for a dynamically controlled crystallization method and apparatus and crystals obtained thereby to Leonard Arnowitz and Emanuel Steinberg, issued Oct. 5, 1999, provides the following background information, “The concept of rational drug design involves obtaining the precise three dimensional molecular structure of a specific protein to permit design of drugs that selectively interact with and adjust the function of that protein. Theoretically, if the structure of a protein having a specified function is known, the function of the protein can be adjusted as desired. This permits a number of diseases and symptoms to be controlled. For example, CAPTOPRIL is a well known drug for controlling hypertension that was developed through rational drug design techniques, CAPTOPRIL inhibits generation of the angiotension-converting enzyme thereby preventing the constriction of blood vessels. The potential for controlling disease through drugs developed by rational drug design is tremendous. X-ray crystallography techniques are utilized to obtain a “fingerprint,” i.e., the precise three-dimensional shape, of a protein crystal. However, a critical step to rational drug design is the ability to reliably crystallize a wide variety of proteins. Therefore, a great deal of time and money have been spent crystallizing proteins for analysis.”

International Patent No. WO02/26342 for an automated robotic device for dynamically controlled crystallization of proteins to Leonard Arnowitz et al, published Apr. 4, 2002, provides the following background information, “There is a pressing need for reliable, high yield, high quality crystallization procedures for rational/structural drug design. Existing screening methods including traditional vapor diffusion experiments, automated systems, and commercial screens are inadequate. For example, once a vapor diffusion experiment is set up with a target concentration of the precipitant used, it cannot be modified. This prolongs the optimization process, and makes it nearly impossible to screen effectively a large number of conditions without a large time commitment and large quantities of protein.”

United States Patent Application No. 2003/0150375 for automated macromolecular crystallization screening to Brent W. Segelke, Bernhard Rupp, and Heike I. Krupka, published Aug. 14, 2003, provides the following state of technology information, a system of automated macromolecular crystallization screening of a sample. Initially, reagent components are selected from a set of reagents and a set of a multiplicity of reagent mixes are produced. A multiplicity of analysis plates are produced utilizing the reagent mixes wherein each analysis plate contains a set format of reagent mixes combined with the sample. The analysis plates are incubated to promote growth of crystals in the analysis plates. Images of the crystals are made. The images are analyzed with regard to suitability of the crystals for analysis by x-ray crystallography. A design of reagent mixes is produced based upon the expected suitability of the crystals for analysis by x-ray crystallography. If the crystals are not ideal, a second multiplicity of mixes of the reagent components is produced utilizing the design. The second multiplicity of reagent mixes are used for automated macromolecular crystallization screening the sample. The second round of automated macromolecular crystallization screening may produce crystals that are suitable for x-ray crystallography. If the second round of crystallization screening does not produce crystals suitable for x-ray crystallography a third reagent mix design is created and a third round of crystallization screening is implemented. If necessary additional reagent mix designs are created and analyzed.

### SUMMARY

Features and advantages of the present invention will become apparent from the following description. Applicants are providing this description, which includes drawings and examples of specific embodiments, to give a broad representation of the invention. Various changes and modifications within the spirit and scope of the invention will become apparent to those skilled in the art from this description and by practice of the invention. The scope of the invention is not intended to be limited to the particular forms disclosed and the invention covers all modifications, equivalents, and alternatives falling within the spirit and scope of the invention as defined by the claims.

The present invention provides a system for crystallization of a protein sample. The system comprises a first mixing cell, a reagent cocktail that is adapted to be added to the first mixing cell, a second mixing cell with the protein sample adapted to be added to the second mixing cell, and a transfer device between the first mixing cell and the second mixing cell. The transfer device comprises structure that allows the reagent cocktail in the first mixing cell to flow into the second mixing cell and mix with the protein sample and allows the protein sample in the second mixing cell to flow into the first mixing cell and mix with the reagent cocktail. The mixture of the reagent cocktail and the protein sample are allowed to incubate to produce protein crystals.

The present invention provides a new type of crystallization labware (or crystallization plate) that enables high-throughput crystallization screening by free-interface diffusion. Crystallization screening is becoming increasingly important in the pharmaceutical industry for structure aided drug design and in basic research for structural genomics. Recent data obtained by Applicants suggests that free-interface diffusion crystallization screening is more successful than other approaches.

Free-interface diffusion crystallization is difficult and expensive to adapt to high throughput. This is primarily due to the lack of available labware that is compatible with existing equipment and procedures. Applicants' invention provides labware that can be used with existing equipment in common use and can be manufactured similarly to existing labware in common use. Applicant's free-interface diffusion crystallization plate can be configured in a variety of ways and from a number of materials. The first instance of the new labware was adapted from an existing 96 cell polystyrene plate. A standard crystallization plate has a place for a “reservoir” solution and a place for a “drop.” Typically, equal volumes of a protein solution and “reservoir solution” are mixed in the “drop” and the drop and reservoir are sealed together in a single micro-environment. The free-interface diffusion plate utilizes separate places for protein solution and a small amount of reservoir solution to be added to the plate and these two locations are connected to each other in some way to allow for mixing by diffusion. In one embodiment of the free-interface diffusion crystallization plate there are two semi-spherical depressions connected by a small channel. The channel is filled with a semi-permeable gel that impedes turbulent mixing but allows for mixing by diffusion.

The invention is susceptible to modifications and alternative forms. Specific embodiments are shown by way of example. It is to be understood that the invention is not limited to the particular forms disclosed. The invention covers all modifications, equivalents, and alternatives falling within the spirit and scope of the invention as defined by the claims.

### BRIEF DESCRIPTION OF THE DRAWINGS

The accompanying drawings, which are incorporated into and constitute a part of the specification, illustrate specific embodiments of the invention and, together with the general description of the invention given above, and the detailed description of the specific embodiments, serve to explain the principles of the invention.

FIG. 1 shows one embodiment of a single unit within a piece of labware for free-interface diffusion crystallization viewed from the top.

FIG. 2 shows another embodiment of a single unit within a piece of labware for free-interface diffusion crystallization viewed from the side.

FIG. 3 shows one embodiment of a complete 96 chamber plate, or piece of labware, for parallel, 96-well, free-interface diffusion crystallization.

FIG. 4 shows a first prototype plate, or piece of labware, for free-interface diffusion crystallization.

FIG. 5 illustrates a successful crystallization experiment, resulting in a protein crystal, using the first prototype free-interface diffusion plate.

FIG. 6 illustrates another embodiment of a single unit within a piece of labware for free-interface diffusion crystallization as viewed from the top.

FIG. 7 illustrates another embodiment of a single unit within a piece of labware for free-interface diffusion crystallization as viewed from the side.

FIG. 8 illustrates another embodiment of a single unit within a piece of labware for free-interface diffusion crystallization as viewed from the top.

FIG. 9 illustrates another embodiment of a single chamber within a piece of labware for free-interface diffusion crystallization as viewed from the side.

FIG. 10 illustrates another embodiment of a single chamber within a piece of labware for free-interface diffusion crystallization as viewed from the side.

FIG. 11 shows a close-up view of the gel filled capillary bridge of the labware for free-interface diffusion crystallization that was illustrated in FIG. 10.

FIG. 12 illustrates another embodiment of a single chamber within a piece of labware for free-interface diffusion crystallization as viewed from the side.

FIG. 13 shows a close-up view of the capillary bridge of the piece of labware for free-interface diffusion crystallization that was illustrated in FIG. 12.

FIG. 14 illustrates one embodiment of a crystallization screening system constructed in accordance with the present invention.

FIG. 15 illustrates a process for free-interface diffusion crystallization in accordance with the present invention using a piece of labware for free-interface diffusion crystallization.

### DETAILED DESCRIPTION OF THE INVENTION

Referring to the drawings, to the following detailed description, and to incorporated materials, detailed information about the invention is provided including the description of specific embodiments. The detailed description serves to explain the principles of the invention. The invention is susceptible to modifications and alternative forms. The invention is not limited to the particular forms disclosed. The invention covers all modifications, equivalents, and alternatives falling within the spirit and scope of the invention as defined by the claims.

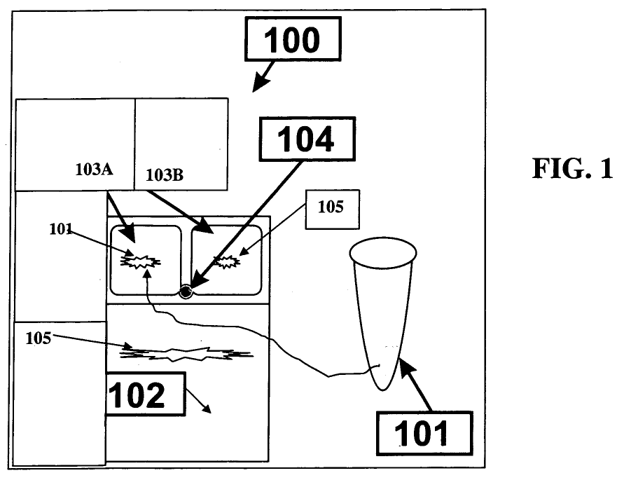

Referring now to FIG. 1, one embodiment of a system constructed in accordance with the present invention is illustrated. The system is designated generally by the reference numeral 100. The system 100 provides labware for sustainable automated high-throughput crystallization screening. Crystallization screening is used in connection with X-ray crystallography. The embodiment of the invention 100 addresses several technical difficulties with efficiently screening for protein crystallization conditions.

Pharmaceutical companies are more and more moving in to high-throughput protein crystallography (structural genomics) for drug development. Deducing protein structure is recognized as “a key element for drug discovery” (The Scientist, Jan. 19, 2004). Given structural information derived from crystallography studies, scientists can design molecules that will bind in the active site of target proteins using computer aided modeling. Arriving at this point still requires a lot of effort to produce protein crystals and therefore methods development in protein crystallization is currently of pressing importance. There have been such tremendous advances in molecular biology and crystallography that a rapid expanse of novel protein structural information awaits only the availability of new protein crystals. Advancement in molecular biology, for example, have made it possible to obtain appreciable quantities of proteins that are not naturally abundant thereby greatly expanding the possible applicability of protein crystallography. The rapid increase in speed and availability of computer resources and increasingly sophisticated software tools, have made rapid structure through x-ray crystallography possible given good quality crystals. Unfortunately, advancements in the field of crystallization have not kept pace with advancements in these other areas. Crystallization is still done by brut force, empirical methods. Automation, miniaturization, and parallelization are currently the major drivers for innovation in protein crystallization.

The objective of protein crystallization is to arrive at a condition that induces the formation of ordered precipitates. Currently there is no way to arrive at such a condition a priori, instead, crystallization is achieved through empirical tests a in a series precipitating conditions. Several factors that influence protein solubility, (e.g., total solute concentration, pH, temperature, etc.) are used in combination to induce precipitation. The total number of combinations of possible factors influencing protein solubility is too large (>300×10e6 combinations) to examine them exhaustively and it is often imperative to arrive at conditions for crystal growth in the fewest possible trials due to scarcity of materials.

There are several methods currently used for protein crystallization and three of these methods have been adapted to procedures that are recognized as high throughput. The three methods currently in use that would be commonly recognized as successfully adapted to high-throughput screening are called: hanging drop vapor diffusion, sitting drop vapor diffusion, and microbatch. A fourth method, referred to as free-interface diffusion (also known as counter diffusion), has been extensively described in scientific literature but has not been adapted to high throughput because of lack of availability of methods or devices that are readily amenable to high-throughput processing. There are fundamental reasons and recent data to suggest that free-interface diffusion would have a significant advantage over other methods if it could be adapted to high-throughput processes. A head-to-head comparison of free-interface diffusion crystallization with sitting drop vapor diffusion carried out at LLNL suggests that free-interface diffusion may be 2-5 times more likely to lead to crystallization compared to sitting drop methods. A microfluidic approach to free-interface diffusion has been recently commercialized and there are efforts to adapt this microfluidics approach to high-throughput processes but this requires highly specialized equipment and consumable costs are prohibitive for large scale screening. The most common approach to free-interface diffusion crystallization, crystallization in capillary tubes, is even more difficult and expensive to automate. The invention we describe here would enable free-interface diffusion crystallization screening that would conform to existing labware standards for automation and would be useable with a wide range of commercially available equipment. Laboratories that are currently setup for high-throughput sitting drop vapor diffusion crystallization screening (the most common high-throughput approach) would not likely need any additional equipment to adapt their processes to the new labware described in this invention.

The embodiment of the invention 100 provides a new type of labware that enables high-throughput crystallization screening by free-interface diffusion. This new labware would provide significant cost savings in equipping for high-throughput crystallization screening by free-interface diffusion compared to currently commercialized approaches, since it enables free-interface diffusion crystallization with currently available liquid handling equipment. This new labware will be significantly cheaper to produce than existing labware for free-interface diffusion as well, since it can be produced by injection molding, thereby reducing consumable costs for high-throughput crystallization by free-interface diffusion. Structural details of the embodiments of the invention shown in FIGS. 1-15 are described below.

Referring again to FIG. 1, the first embodiment of a crystallization screening system constructed in accordance with the present invention is illustrated. The crystallization screening system is designated generally by the reference numeral 100. Crystallization screening is used in connection with X-ray crystallography. The crystallization screening system 100 is a single unit within a piece of labware for free-interface diffusion crystallization. The crystallization screening system 100 is illustrated as viewed from the top in FIG. 1. The structural elements of the crystallization screening system 100 include a protein sample 101 to be crystallized, an optional reservoir 102 of reagent cocktail, a left mixing cell 103A, a right mixing cell 103B, and a water permeable plug 104 between the left mixing cell 103A and the right mixing cell 103B. The system 100 provides labware for sustainable automated high-throughput crystallization screening. The embodiment of the invention 100 addresses several technical difficulties with efficiently screening for protein crystallization conditions.

The structural details of an embodiment of the invention shown in FIG. 1 having been described, the operations of the crystallization screening system 100 will now be considered. To setup a single crystallization experiment with Applicant's new labware for high-throughput free-interface diffusion crystallization, the reagent cocktail 105 previously derived, is added to the to the right mixing cell 103B. A reagent cocktail 105 previously derived may also be added to the reservoir 102; however, the addition of the reagent cocktail 105 to the reservoir 102 is optional.

The protein sample 101 is added to the left mixing cell 103A. The order and arrangement of the protein sample 101 and reagent cocktail 105 in the mixing cells 103A and 103B is not critical so long as they are in separate mixing cells that are in contact through the water permeable plug 104. Following the addition of reagent cocktail 105 to the right mixing cell 103B and addition of the protein sample 101 to the left mixing cell 103A, (and if desired addition of the reagent cocktail 105 to the reservoir 102) the chamber is sealed and allowed to incubate. As the crystallization experiment incubates, the reagent cocktail 105 and protein sample 101 slowly diffuse into each other through the water permeable plug 104. When the right combination of reagent 105 and protein sample 101 is used, protein crystals form.

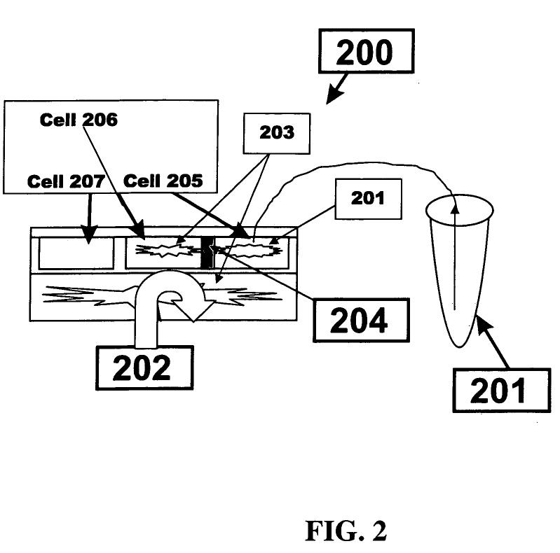

Referring now to FIG. 2, another embodiment of a chamber unit within a piece of labware for free-interface diffusion crystallization is illustrated as viewed from the side. The chamber system is designated generally by the reference numeral 200. The structural elements of the chamber crystallization screening system 200 include a protein sample 201 to be crystallized, a reservoir 201, a reagent cocktail 203, a water permeable plug 204, a sample mixing cell 205, a reagent mixing cell 206, and an extra mixing cell 207.

The structural details of the embodiment of the chamber crystallization screening system 200 shown in FIG. 2 having been described, the operation of the crystallization screening system 200 will now be considered. To setup a crystallization experiment, the reagent cocktail 203 previously derived, is added to the reagent mixing cell 206. The reagent cocktail 203 previously derived may also be added to the reservoir 202; however, the addition of the reagent cocktail 203 to the reservoir 202 is optional.

The protein sample 201 is added to the sample mixing cell 205. An extra mixing cell 207 is shown adjacent the reagent mixing cell 206. This extra mixing cell is not used in the system being described but could be used for more complex crystallization experiments. The order and arrangement of the protein sample 201 and reagent cocktail 203 in the mixing cells 205 and 206 is not critical so long as they are in separate mixing cells that are in contact through the water permeable plug 204. Following the addition of reagent cocktail 203 to the reagent mixing cell 206 and addition of the protein sample 201 to the sample mixing cell 205, (and if desired addition of the reagent cocktail 203 to the reservoir 202) the chamber is sealed and allowed to incubate. As the crystallization experiment incubates, the reagent cocktail 203 and protein sample 201 slowly diffuse in to each other through the water permeable plug 204. When the right combination of reagent 203 and protein sample 201 is used, protein crystals form.

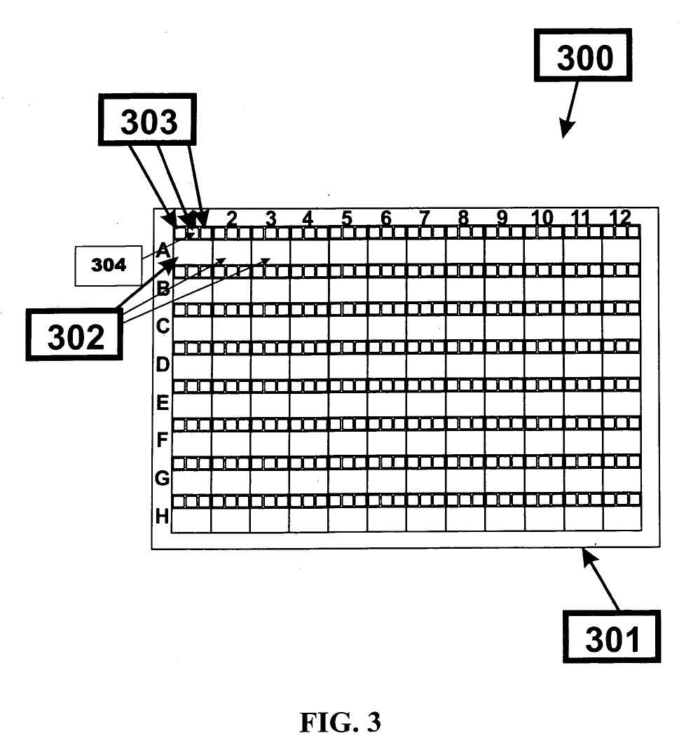

Referring now to FIG. 3, an embodiment of a complete 96 chamber plate, or piece of labware, for parallel, 96-well, free-interface diffusion crystallization is illustrated. The 96 chamber plate, or piece of labware, for parallel, 96-well, free-interface diffusion crystallization is designated generally by the reference numeral 300. The structural elements of the 96 chamber plate, or piece of labware, for parallel, 96-well, free-interface diffusion crystallization 300 comprise a 96-well free-interface diffusion plate 301 with eight rows (rows A through H) and twelve columns (columns 1 through 12) of chamber units for free-interface diffusion crystallization. This provides 96 separate chamber units for free-interface diffusion crystallization. Each chamber unit comprises a reservoir 302, three mixing cells 303, and a transfer device 304 between adjacent mixing cells 303. Two mixing cells are used as previously described; however, all three mixing cells could be used for more complex crystallization experiments. The transfer device 304 may be a water permeable plug, a channel, a bridge, a membrane, or other form of transfer device.

The structural details of the embodiment of the 96 chamber plate, or piece of labware, for parallel, 96-well, free-interface diffusion crystallization 300 shown in FIG. 3 having been described, the operation of the 96 chamber plate, or piece of labware, for parallel, 96-well, free-interface diffusion crystallization 300 will now be considered. To setup a crystallization experiment, a predetermined composition of a reagent cocktail is added to one of the reagent mixing cells 303 in each of the 96 chamber unit being used in the experiment. The reagent cocktail may also be added to the reservoir 302; however, the addition of the reagent cocktail to the reservoir 302 is optional.

The protein sample is added to each adjacent sample mixing cell 303 next to the mixing cell containing the reagent cocktail. A third mixing cell is shown. This third mixing cell is not used in the system being described but could be used for more complex crystallization experiments. The protein sample and reagent cocktail in the mixing cells 303 are in separate mixing cells that are in contact through the water permeable plug 304. Following the addition of reagent cocktail to the individual reagent mixing cells and addition of the protein sample to the individual sample mixing cells and, if desired, addition of the reagent cocktail to the reservoirs 302 the chambers are sealed and allowed to incubate. As the crystallization experiment incubates, the reagent cocktail and protein sample slowly diffuse in to each other through the water permeable plug. When the right combination of reagent and protein sample is used, protein crystals form.

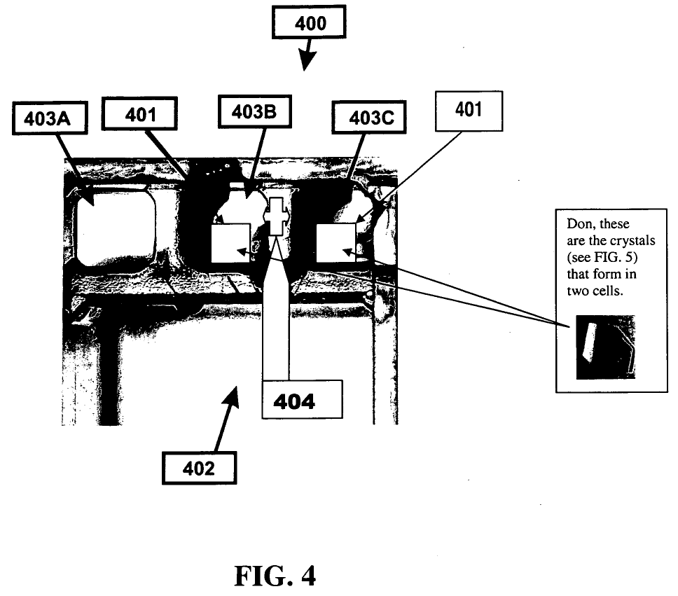

Referring now to FIG. 4, the reduction to practice of a first prototype plate, or piece of labware, for free-interface diffusion crystallization is illustrated. One chamber 400 within a piece of labware for free-interface diffusion crystallization is shown in FIG. 4. The chamber 400 was photographed from above the chamber. The structural elements shown include a crystal 401 obtained through free-interface diffusion, a reservoir 402 of crystallization cocktail, a left mixing cell 403A (unused), a middle mixing cell, protein cell 403B, a right mixing cell, reagent cell 403C, and an agarose gel plug 404.

To setup the crystallization experiment, a predetermined composition of a reagent cocktail is added to the reagent mixing cell 403C. The reagent cocktail is also be added to the reservoir 402; however, the addition of the reagent cocktail to the reservoir 402 is optional and is not required. The protein sample is added to the sample mixing cell 403B next to the reagent cocktail mixing cell 403C. A third mixing cell 403A is shown. This third mixing cell was not used in the system being described but could be used for more complex crystallization experiments.

The protein sample and reagent cocktail in the sample mixing cell 403B and the reagent cocktail mixing cell 403C are in contact through the agarose gel plug 404. The chamber was sealed and allowed to incubate. After the crystallization experiment incubated, the reagent cocktail and protein sample slowly diffused in through the agarose gel plug 404. The reagent cocktail from reagent cocktail mixing cell 403B flows into sample mixing cell 403C and the sample from sample mixing cell 403 flows into reagent cocktail mixing cell 403B. The right combination of reagent and protein sample were used and protein crystals 404 formed in the sample mixing cell 403B and reagent cocktail mixing cell 403C.

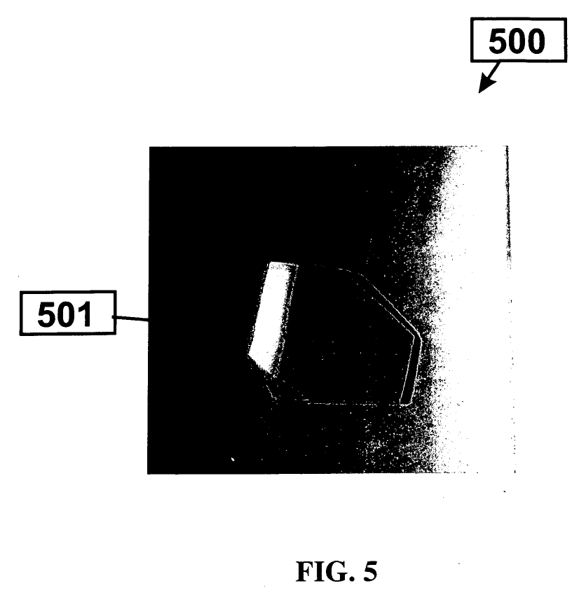

Referring now to FIG. 5, a successful crystallization experiment, resulting in a protein crystal, using the first prototype free-interface diffusion plate is illustrated. The right combination of reagent cocktail and protein sample were used and the protein crystal 501 was formed.

A predetermined composition of a reagent cocktail was added to a reagent mixing cell. A protein sample was added to a sample mixing cell next to the reagent cocktail mixing cell. The protein sample and reagent cocktail in the sample mixing cells were in contact through a permeable plug. The chamber was sealed and allowed to incubate. After the crystallization experiment incubated, the reagent cocktail and protein sample slowly diffused in through the permeable plug. The right combination of reagent and protein sample was used and the protein crystal 501 formed.

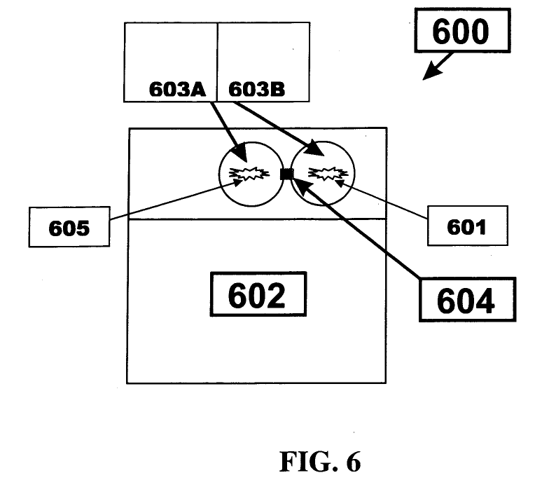

Referring now to FIG. 6, another embodiment of a single chamber within a piece of labware for free-interface diffusion crystallization is illustrated as viewed from the top. This embodiment of a single chamber within a piece of labware for free-interface diffusion crystallization is designated generally by the reference numeral 600. The structural elements of the single chamber within a piece of labware for free-interface diffusion crystallization 600 includes a protein sample to be crystallized 601, a reservoir 602, a mixing cell 603A, a mixing cell 603B, and permeable plug 604. The mixing cells 603A and 603B are cylindrical and the permeable plug 604 is pressed in from the bottom.

The structural details of an embodiment of the invention shown in FIG. 6 having been described, the operations of the crystallization screening system 600 will now be considered. To setup a single crystallization experiment with Applicant's new labware for high-throughput free-interface diffusion crystallization, a reagent cocktail 605 previously derived, is added to the to the reagent mixing cell 603A. The reagent cocktail 605 previously derived may also be added to the reservoir 602; however, the addition of the reagent cocktail 605 to the reservoir 602 is optional.

The protein sample 601 is added to the sample mixing cell 603B. The order and arrangement of the protein sample 601 and reagent cocktail 605 in the mixing cells 603A and 603B is not critical so long as they are in separate mixing cells that are in contact through the permeable plug 604. Following the addition of the reagent cocktail 605 to the mixing cell 603A and addition of the protein sample 601 to the mixing cell 603B, the chamber is sealed and allowed to incubate. As the crystallization experiment incubates, the reagent cocktail 605 and protein sample 601 slowly diffuse in to each other through the water permeable plug 604. When the right combination of reagent 605 and protein sample 601 is used, protein crystals form.

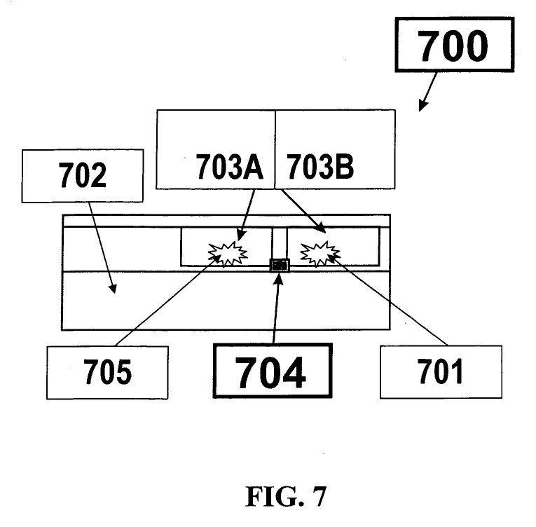

Referring now to FIG. 7, another embodiment of a single chamber within a piece of labware for free-interface diffusion crystallization is illustrated as viewed from the side. This embodiment of a single chamber within a piece of labware for free-interface diffusion crystallization is designated generally by the reference numeral 700. The structural elements of the single chamber within a piece of labware for free-interface diffusion crystallization 700 includes a protein sample to be crystallized 701, a reservoir 702, a mixing cell 703A, a mixing cell 703B, and permeable plug 704. The mixing cells 703A and 703B are cylindrical and the permeable plug 704 is pressed in from the bottom.

The structural details of an embodiment of the invention shown in FIG. 7 having been described, the operations of the crystallization screening system 700 will now be considered. To setup a single crystallization experiment with Applicant's new labware for high-throughput free-interface diffusion crystallization, a reagent cocktail 705 previously derived, is added to the to the reagent mixing cell 703A. The reagent cocktail 705 previously derived may also be added to the reservoir 702; however, the addition of the reagent cocktail 705 to the reservoir 702 is optional.

The protein sample 701 is added to the sample mixing cell 703B. The order and arrangement of the protein sample 701 and reagent cocktail 705 in the mixing cells 703A and 703B is not critical so long as they are in separate mixing cells that are in contact through the permeable plug 704. Following the addition of the reagent cocktail 705 to the mixing cell 703A and addition of the protein sample 701 to the mixing cell 703B, the chamber is sealed and allowed to incubate. As the crystallization experiment incubates, the reagent cocktail 705 and protein sample 701 slowly diffuse in to each other through the water permeable plug 704. When the right combination of reagent 705 and protein sample 701 is used, protein crystals form.

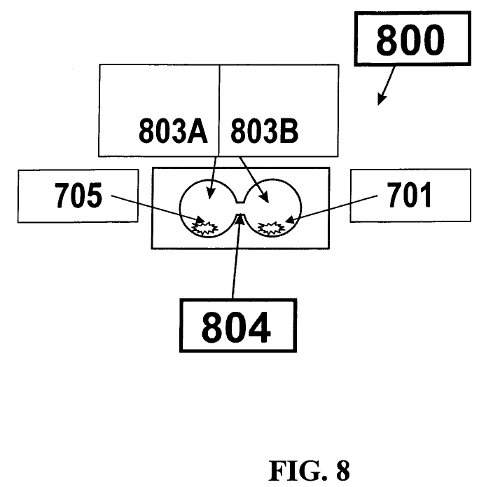

Referring now to FIG. 8, another embodiment of a single chamber within a piece of labware for free-interface diffusion crystallization is illustrated as viewed from the top. This embodiment of a single chamber within a piece of labware for free-interface diffusion crystallization is designated generally by the reference numeral 800. The structural elements of the single chamber within a piece of labware for free-interface diffusion crystallization 800 includes a protein sample to be crystallized 801, a mixing cell 803A, a mixing cell 803B, and capillary channel 804. The mixing cells 803A and 803B are cylindrical and the capillary channel 804 is pressed in from the bottom.

The structural details of an embodiment of the invention shown in FIG. 8 having been described, the operations of the crystallization screening system 800 will now be considered. To setup a single crystallization experiment with Applicant's new labware for high-throughput free-interface diffusion crystallization, a reagent cocktail 805 previously derived, is added to the to the reagent mixing cell 803A. The protein sample 801 is added to the sample mixing cell 803B. The order and arrangement of the protein sample 801 and reagent cocktail 805 in the mixing cells 803A and 803B is not critical so long as they are in separate mixing cells that are in contact through the capillary channel 804. Following the addition of the reagent cocktail 805 to the mixing cell 803A and addition of the protein sample 801 to the mixing cell 803B, the chamber is sealed and allowed to incubate. As the crystallization experiment incubates, the reagent cocktail 805 and protein sample 801 slowly diffuse in to each other through the water capillary channel 804. When the right combination of reagent 805 and protein sample 801 is used, protein crystals form.

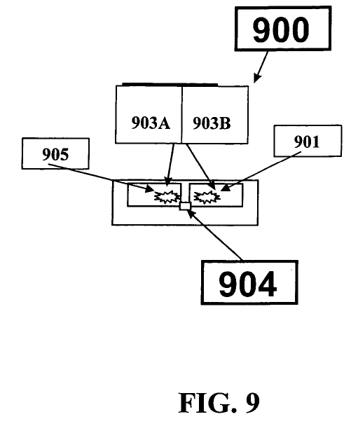

Referring now to FIG. 9, another embodiment of a single chamber within a piece of labware for free-interface diffusion crystallization is illustrated as viewed from the side. This embodiment of a single chamber within a piece of labware for free-interface diffusion crystallization is designated generally by the reference numeral 900. The structural elements of the single chamber within a piece of labware for free-interface diffusion crystallization 900 includes a protein sample to be crystallized 901, a mixing cell 903A, a mixing cell 903B, and capillary channel 904. The mixing cells 903A and 903B are cylindrical and the capillary channel 904 is pressed in from the bottom.

The structural details of an embodiment of the invention shown in FIG. 9 having been described, the operations of the crystallization screening system 900 will now be considered. To setup a single crystallization experiment with Applicant's new labware for high-throughput free-interface diffusion crystallization, a reagent cocktail 905 previously derived, is added to the to the reagent mixing cell 903A. The protein sample 901 is added to the sample mixing cell 903B. The order and arrangement of the protein sample 901 and reagent cocktail 905 in the mixing cells 903A and 903B is not critical so long as they are in separate mixing cells that are in contact through the capillary channel 904. Following the addition of the reagent cocktail 905 to the mixing cell 903A and addition of the protein sample 901 to the mixing cell 903B, the chamber is sealed and allowed to incubate. As the crystallization experiment incubates, the reagent cocktail 905 and protein sample 901 slowly diffuse in to each other through the capillary channel 904. When the right combination of reagent 905 and protein sample 901 is used, protein crystals form.

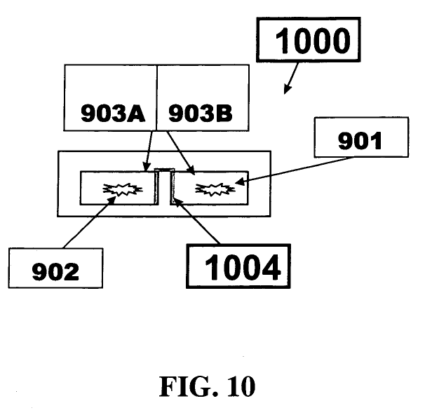

Referring now to FIG. 10, another embodiment of a single chamber within a piece of labware for free-interface diffusion crystallization is illustrated as viewed from the side. This embodiment of a single chamber within a piece of labware for free-interface diffusion crystallization is designated generally by the reference numeral 1000. The structural elements of the single chamber within a piece of labware for free-interface diffusion crystallization 1000 includes a protein sample to be crystallized 1001, a mixing cell 1003A, a mixing cell 1003B, and gel filled capillary bridge 1004.

The structural details of an embodiment of the invention shown in FIG. 10 having been described, the operations of the crystallization screening system 1000 will now be considered. To setup a single crystallization experiment with Applicant's new labware for high-throughput free-interface diffusion crystallization, a reagent cocktail 1005 previously derived, is added to the to the reagent mixing cell 1003A. The protein sample 1001 is added to the sample mixing cell 1003B. The order and arrangement of the protein sample 1001 and reagent cocktail 1005 in the mixing cells 1003A and 1003B is not critical so long as they are in separate mixing cells that are in contact through the gel filled capillary bridge 1004. Following the addition of the reagent cocktail 1005 to the mixing cell 1003A and addition of the protein sample 1001 to the mixing cell 1003B, the chamber is sealed and allowed to incubate. As the crystallization experiment incubates, the reagent cocktail 1005 and protein sample 1001 slowly diffuse in to each other through the gel filled capillary bridge 1004. When the right combination of reagent 1005 and protein sample 1001 is used, protein crystals form.

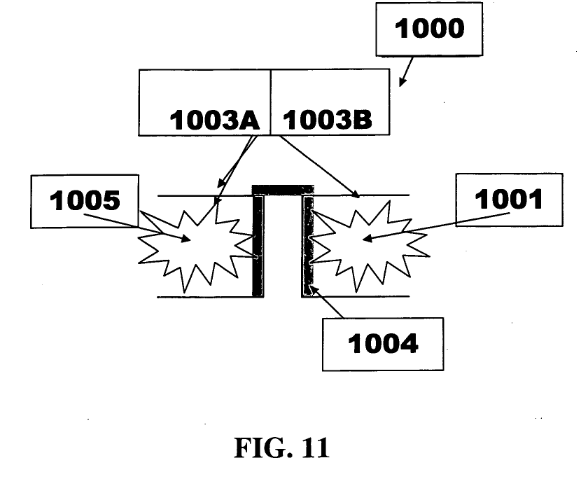

Referring now to FIG. 11, a closeup view is shown of the gel filled capillary bridge 1004 of the piece of labware for free-interface diffusion crystallization 1000 that was illustrated in FIG. 10. The structural elements include the protein sample to be crystallized 1001, the mixing cell 1003A, the mixing cell 1003B, and the gel filled capillary bridge 1004. To setup a single crystallization experiment with Applicant's new labware for high-throughput free-interface diffusion crystallization, a reagent cocktail 1005 previously derived, is added to the to the reagent mixing cell 1003A. The protein sample 1001 is added to the sample mixing cell 1003B. The order and arrangement of the protein sample 1001 and reagent cocktail 1005 in the mixing cells 1003A and 1003B is not critical so long as they are in separate mixing cells that are in contact through the gel filled capillary bridge 1004. Following the addition of the reagent cocktail 1005 to the mixing cell 1003A and addition of the protein sample 1001 to the mixing cell 1003B, the chamber is sealed and allowed to incubate. As the crystallization experiment incubates, the reagent cocktail 1005 and protein sample 1001 slowly diffuse in to each other through the gel filled capillary bridge 1004. When the right combination of reagent 1005 and protein sample 1001 is used, protein crystals form.

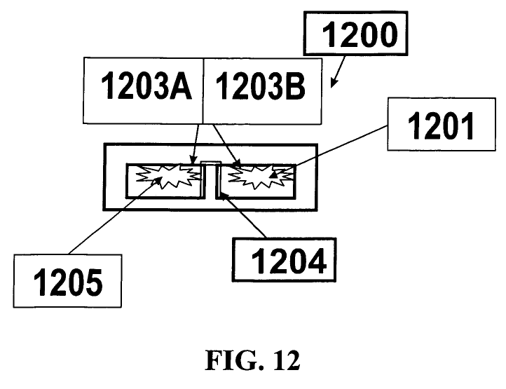

Referring now to FIG. 12, another embodiment of a single chamber within a piece of labware for free-interface diffusion crystallization is illustrated as viewed from the side. This embodiment of a single chamber within a piece of labware for free-interface diffusion crystallization is designated generally by the reference numeral 1200. The structural elements of the single chamber within a piece of labware for free-interface diffusion crystallization 1200 includes a protein sample to be crystallized 1201, a mixing cell 1203A, a mixing cell 1203B, and capillary bridge 1204. This embodiment differs from that shown in FIG. 1 in that mixing cells 1203A and 1203B are cylindrical and that the permeable plug is replaced by a capillary bridge 1204. This embodiment differs from that shown in FIGS. 10 and 11 in that the capillary bridge 1204 is not filled with gel.

The structural details of an embodiment of the invention shown in FIG. 12 having been described, the operations of the crystallization screening system 1200 will now be considered. To setup a single crystallization experiment with Applicant's new labware for high-throughput free-interface diffusion crystallization, a reagent cocktail 1205 previously derived, is added to the to the reagent mixing cell 1203A. The protein sample 1201 is added to the sample mixing cell 1203B. The order and arrangement of the protein sample 1201 and reagent cocktail 1205 in the mixing cells 1203A and 1203B is not critical so long as they are in separate mixing cells that are in contact through the capillary bridge 1204. Following the addition of the reagent cocktail 1205 to the mixing cell 1203A and addition of the protein sample 1201 to the mixing cell 1203B, the chamber is sealed and allowed to incubate. As the crystallization experiment incubates, the reagent cocktail 1205 and protein sample 1201 slowly diffuse in to each other through the capillary bridge 1204. When the right combination of reagent 1205 and protein sample 1201 is used, protein crystals form.

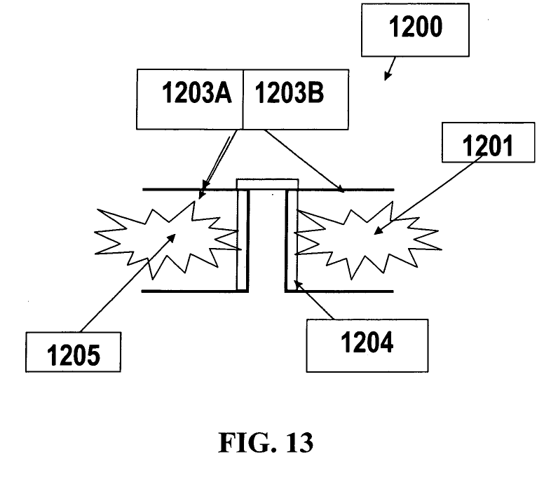

Referring now to FIG. 13, a closeup view is shown of the capillary bridge 1204 of the piece of labware for free-interface diffusion crystallization 1200 that was illustrated in FIG. 12. The structural elements include the protein sample to be crystallized 1201, the mixing cell 1203A, the mixing cell 1203B, and the capillary bridge 1204. To setup a single crystallization experiment with Applicant's new labware for high-throughput free-interface diffusion crystallization, a reagent cocktail 1205 previously derived, is added to the to the reagent mixing cell 1203A. The protein sample 1201 is added to the sample mixing cell 1203B. The order and arrangement of the protein sample 1201 and reagent cocktail 1205 in the mixing cells 1203A and 1203B is not critical so long as they are in separate mixing cells that are in contact through the capillary bridge 1204. Following the addition of the reagent cocktail 1205 to the mixing cell 1203A and addition of the protein sample 1201 to the mixing cell 1203B, the chamber is sealed and allowed to incubate. As the crystallization experiment incubates, the reagent cocktail 1205 and protein sample 1201 slowly diffuse in to each other through the capillary bridge 1204. When the right combination of reagent 1205 and protein sample 1201 is used, protein crystals form.

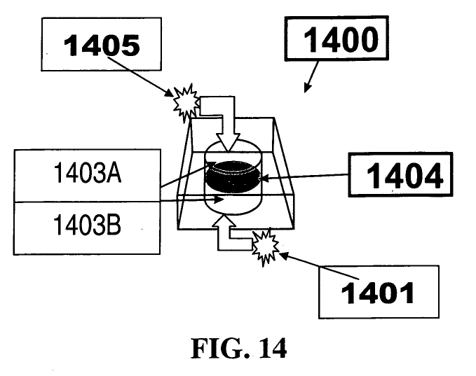

Referring now to FIG. 14, one embodiment of a crystallization screening system constructed in accordance with the present invention is illustrated. The crystallization screening system is designated generally by the reference numeral 1400. The structural elements of the crystallization screening system 1400 include a protein sample 1401 to be crystallized, a reagent mixing cell 1403A, a sample mixing cell 1403B, and a water permeable plug 1404 between the mixing cell 1403A and the mixing cell 1403B. The system 1400 provides labware for sustainable automated high-throughput crystallization screening.

The structural details of an embodiment of the invention shown in FIG. 14 having been described, the operations of the crystallization screening system 1400 will now be considered. The reagent cocktail 1405 previously derived, is added to the mixing cell 1403B. The protein sample 1401 is added to the mixing cell 1403A. The order and arrangement of the protein sample 1401 and reagent cocktail 1405 in the mixing cells 1403A and 1403B is not critical so long as they are in separate mixing cells that are in contact through the water permeable plug 1404. Following the addition of reagent cocktail 1405 to the mixing cell 1403B and addition of the protein sample 1401 to the mixing cell 1403A, the chamber is sealed and allowed to incubate. As the crystallization experiment incubates, the reagent cocktail 1405 and protein sample 1401 slowly diffuse into each other through the water permeable plug 1404. When the right combination of reagent 1405 and protein sample 1401 is used, protein crystals form.

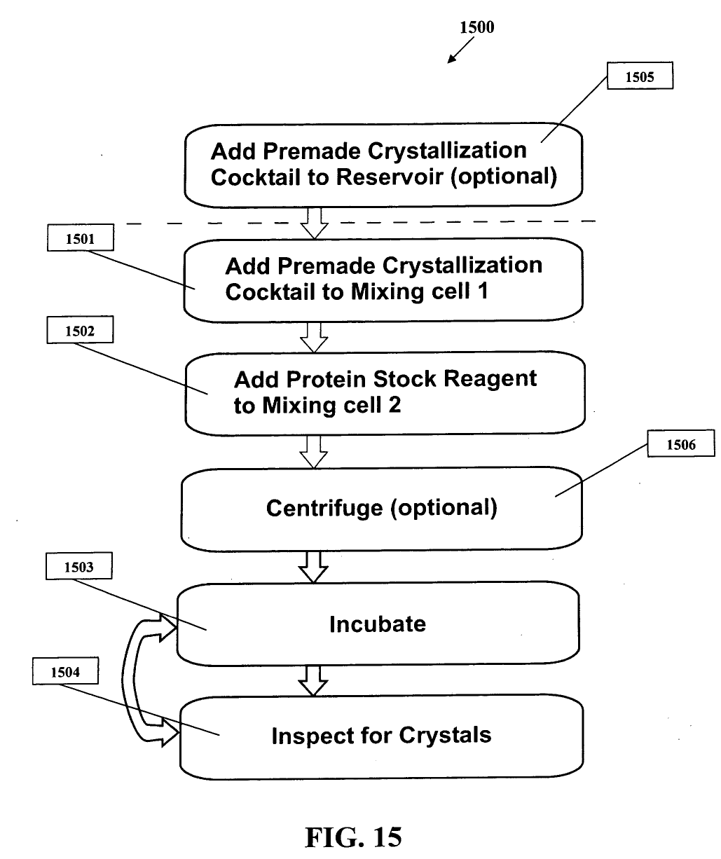

Referring now to FIG. 15, another embodiment of a process for free-interface diffusion crystallization in accordance with the present invention using a piece of labware for free-interface diffusion crystallization is illustrated. A crystallization experiment with Applicant's new labware for high-throughput free-interface diffusion comprises providing a first mixing cell, providing a second mixing cell, providing a transfer device between the first mixing cell and the second mixing cell, adding a reagent cocktail to the first mixing cell, adding the protein sample to the second mixing cell, allowing the reagent cocktail and the protein sample to mix through the transfer device creating a mixture of the reagent cocktail and the protein sample, and incubating the mixture to produce the protein crystals.

The crystallization screening system is designated generally by the reference numeral 1500. Crystallization screening is used in connection with X-ray crystallography. The crystallization screening system 1500 provides a process for free-interface diffusion crystallization. The process 1500 for free-interface diffusion crystallization includes the following steps: step 1501 addition of premade crystallization cocktail or reagent to mixing cell 1; step 1502 addition of premade protein stock reagent (the sample) to mixing cell 2; and steps 1503 and 1504, iterative incubation (step 1503) and inspection (1504) for crystals. The process 1500 for free-interface diffusion crystallization can also include the optional step 1505 addition of premade crystallization cocktail or reagent to a reservoir and step 1503 optional centrifugation.

The structural details of embodiments of the invention shown in FIGS. 1-15 having been described, the operations of the systems will now be described. To setup a single crystallization experiment with the new labware for high-throughput free-interface diffusion crystallization, a reagent cocktail, previously derived, is added to the right mixing cell, i.e., mixing cell 103B in FIG. 1. A protein stock reagent (the sample) is added to the left mixing, i.e., mixing cell 103A in FIG. 1. The order and arrangement of protein stock and reagent cocktail in the mixing cells is not critical so long as they are in separate mixing cells that are in contact through the transfer device, i.e., water permeable plug 104 in FIG. 1. Following the addition of reagent cocktail to the reservoir and the mixing cell and addition of sample to the mixing cell, the chamber is sealed and allowed to incubate. To setup a 96 crystallization experiment, illustrated in FIG. 3, the process for one crystallization experiment is repeated 96 times in the 96-well plate, but with a different reagent cocktail used in each reagent mixing cell chamber and the whole plate is sealed. As the crystallization experiments incubate, reagent cocktail and sample slowly diffuse in to each other through the transfer device. If the right combination of reagents is used in the reagent cocktail, protein crystals are formed as illustrated in FIGS. 4 and 5.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

The invention claimed is:

1. A system for crystallization of a protein sample, comprising:
a first mixing cell,
a reagent cocktail, said reagent cocktail adapted to be added to said first mixing cell,
a second mixing cell,
the protein sample adapted to be added to said second mixing cell, and
a transfer device between said first mixing cell and said second mixing cell.

2. The system for crystallization of claim 1 wherein said transfer device comprises structure that allows said reagent cocktail in said first mixing cell to flow into said second mixing cell and mix with the protein sample and allows the protein sample in said second mixing cell to flow into said first mixing cell and mix with said reagent cocktail.

3. The system for crystallization of claim 1 wherein said transfer device comprises means for allowing said reagent cocktail in said first mixing cell to flow into said second mixing cell and mix with the protein sample and allowing the protein sample in said second mixing cell to flow into said first mixing cell and mix with said reagent cocktail.

4. The system for crystallization of claim 1 wherein said transfer device comprises a water permeable plug or a channel or a bridge or a membrane or a capillary bridge or a gel filled capillary bridge that allows said reagent cocktail in said first mixing cell to flow into said second mixing cell and mix with the protein sample and allows the protein sample in said second mixing cell to flow into said first mixing cell and mix with said reagent cocktail.

5. The system for crystallization of claim 1 wherein said transfer device is a water permeable plug.

6. The system for crystallization of claim 1 wherein said transfer device is a channel.

7. The system for crystallization of claim 1 wherein said transfer device is a membrane.

8. The system for crystallization of claim 1 wherein said transfer device is a capillary bridge.

9. The system for crystallization of claim 1 wherein said transfer device is a gel filled capillary bridge.

10. The system for crystallization of claim 1 wherein said first mixing cell has a parallelogram shape.

11. The system for crystallization of claim 1 wherein said first mixing cell and said second mixing cell have a parallelogram shape.

12. The system for crystallization of claim 1 wherein said first mixing cell is cylindrical.

13. The system for crystallization of claim 1 wherein said first mixing cell and said second mixing cell are cylindrical.

14. The system for crystallization of claim 1 including a reservoir connected to said first mixing cell and said second mixing cell.

15. The system for crystallization of claim 1 including a reservoir connected to said first mixing cell with said reagent cocktail in said reservoir.

16. The system for crystallization of claim 1 including a chamber plate with said first mixing cell, said second mixing cell, and said transfer device connected to said chamber plate.

17. The system for crystallization of claim 1 including a multi-chamber plate with said first mixing cell, said second mixing cell, and said transfer device connected to said multi-chamber plate and including at least one reagent mixing cell, at least one sample mixing cell, and at least one transfer device connected to said multi-chamber plate.

18. The system for crystallization of claim 1 including a ninety six chamber plate with said first mixing cell, said second mixing cell, and said transfer device connected to said ninety six chamber plate and including additional reagent mixing cells, additional sample mixing cells, and additional transfer devices make up said ninety six chamber plate.

19. A method of crystallization for producing protein crystals, comprising:
providing a first mixing cell,
providing a second mixing cell,
providing a transfer device between said first mixing cell and said second mixing cell,
adding a reagent cocktail to said first mixing cell,
adding the protein sample to said second mixing cell,
allowing said reagent cocktail and the protein sample to mix through said transfer device creating a mixture of said reagent cocktail and the protein sample, and
incubating said mixture of said reagent cocktail and the protein sample to produce the protein crystals.

20. The method of crystallization of claim 19 wherein said step of adding a reagent cocktail to said first mixing cell comprises adding a reagent cocktail, previously derived to said first mixing cell.

21. The method of crystallization of claim 19 including the steps of providing a reservoir connected to said first mixing cell and adding said reagent cocktail to said reservoir.
